(19) United States
(12) Patent Application Publication
(10) Pub. No.: US 2010/0173437 A1
(43) Pub. Date: Jul. 8, 2010

(54) Method of fabricating CMUTs that generate low-frequency and high-intensity ultrasound

(76) Inventors: Ira O. Wygant, Palo alto, CA (US); Mario Kupnik, Mountain View, CA (US); Butrus T. Khuri-Yakub, Palo Alto, CA (US)

Correspondence Address: LUMEN PATENT FIRM, 350 Cambridge Avenue, Suite 100, PALO ALTO, CA, 94306, US

(21) Appl. No.: 12/589,364

(22) Filed: Oct. 21, 2009

Related U.S. Application Data
(60) Provisional application No. 61/196,941, filed on Oct. 21, 2008.

(51) Int. Cl. H01L 21/302

(52) U.S. Cl. 438/53; 257/E21.214

(57) ABSTRACT

The present invention provides a method of fabricating low-frequency and high-intensity ultrasound CMUTs that includes using deep reactive ion (DRIE) etching to etch at least one cavity in a first surface of a conductive silicon wafer, growing an insulating layer on at least the first surface of the conductive silicon wafer, bonding a silicon layer of a SOI wafer to the insulating layer, where the SOI wafer includes a handle layer, a buried oxide layer and a conductive silicon layer. The handle layer and the buried oxide layer of the SOI wafer are removed, where the conductive layer of the SOI wafer forms a membrane across at least one cavity, and electrically isolating at least one the membrane across the at least one cavity, where at least one the low-frequency and high-intensity ultrasound CMUT is provided.

### CROSS-REFERENCE TO RELATED APPLICATIONS

This application claims priority from U.S. Provisional Patent Application 61/196,941 filed Oct. 21, 2008, which is incorporated herein by reference.

### STATEMENT REGARDING FEDERALLY SPONSORED RESEARCH OR DEVELOPMENT

This invention was made with Government support under contract N66001-06-1-2032 awarded by SPA WAR System Center. The US Government has certain rights in the invention.

### FIELD OF THE INVENTION

The present invention relates generally to capacitive micromachined ultrasonic transducer (CMUT). More particularly, the invention relates to a method for fabricating large-area CMUTs that are particularly suited for the generation of high-intensity ultrasound in the kilohertz to hundreds of kilohertz frequency range.

### BACKGROUND

Ultrasonic applications in the kilohertz to hundreds of kilohertz range sometimes require capacitive micromachined ultrasonic transducer (CMUT) designs with large membrane and cavity dimensions. For example, some designs may require membranes several millimeters in diameter and cavities that are tens of microns or more deep. CMUTs with dimensions on this order cannot be reliably fabricated with conventional CMUT fabrication techniques, which were typically developed for CMUTs operating in the megahertz range.

CMUT fabrication methods can be broadly categorized into sacrificial release techniques and wafer bonding techniques. Sacrificial release techniques define the cavity region using built-up regions of sacrificial material such as polysilicon. As a result, sacrificial release techniques are not well suited for cavities deeper than several microns. Additionally, sacrificial release techniques generally use silicon nitride as the membrane material, which suffers from unpredictable mechanical properties.

Existing CMUT fabrication methods were typically developed for high-frequency applications (e.g. medical imaging) where the membrane dimensions, oxide thicknesses, and cavity depths are on a much smaller scale. As a result, existing methods cannot be directly applied to the fabrication of CMUTs with larger dimensions.

The dominant technologies for generating and detecting low-frequency ultrasound are conventional capacitive transducers and transducers based on piezoelectric material. Conventional capacitive transducers are fabricated partially or completely without micromachining methods. As a result, their design is limited in ways that CMUTs are not.

For example, unconventional membrane profiles cannot be created with conventional capacitive transducer fabrication techniques. Additionally, it is difficult to reliably vacuum-seal the cavities of conventional capacitive transducers.

Transducers based on piezoelectric crystals have high-transmit and receive sensitivities, but typically have narrow bandwidths, particularly in air. Transducers based on piezoelectric polymers such as PVDF have wider bandwidths but lower transmit and receive sensitivities. Additionally, piezoelectric materials tend to be lossy, which makes them less efficient and potentially undesirable for high-power applications.

Accordingly, there is a need to develop a method of manufacturing large-area, low-frequency micromachined ultrasonic transducers.

### SUMMARY OF THE INVENTION

The present invention provides a method of fabricating low-frequency and high-intensity ultrasound CMUTs that includes using deep reactive ion (DRIE) etching to etch at least one cavity in a first surface of a conductive silicon wafer, growing an insulating layer on at least the first surface of the conductive silicon wafer, bonding a silicon layer of a SOI wafer to the insulating layer, wherein the SOI wafer includes a handle layer, a buried oxide layer and the silicon layer, removing the handle layer and the buried oxide layer of the SOI wafer, where the silicon layer of the SOI wafer forms a membrane across the at least one cavity, and electrically isolating at least one the membrane across the at least one cavity, where at least one the low-frequency and high-intensity ultrasound CMUT is provided.

According to one aspect of the invention, the low-frequency and high-intensity ultrasound CMUT the further includes providing an electrode on the membrane.

In another aspect of the invention, the bonding is done in a vacuum environment to provide a vacuum-sealed cavity.

In a further aspect, the bonding includes annealing in an oxidation furnace.

According to another aspect, the removing the handle layer and the buried oxide layer includes grinding and etching.

In one aspect the low-frequency and high-intensity ultrasound CMUT further has an electrode on a second surface of the conductive silicon wafer.

According to a further aspect of the invention, a profile of the at least one cavity is defined by optical lithography. Here, the optical lithography includes a first optical exposure and at least a second optical exposure, where a mask of the photolithography is rotated between the exposures. Further, the mask is cleaned between each the exposure.

In another aspect, the DRIE etching includes anisotropic DRIE etching or isotropic DRIE etching.

In yet another aspect of the invention, a thickness of the membrane is in a range of 1 μm to 500 μm.

In a further aspect, a cross-section length of the membrane is in a range of about 100 μm to 10 mm.

According to another aspect, a depth of the cavity is in a range of 1 μm to 500 μm.

In a further aspect, a cross-section length of the cavity is in a range 100 μm to 10 mm.

In one aspect of the invention, a ratio of a cross-section length to of the membrane a thickness of the membrane is in a range of 0.01 to 500.

In another aspect, the conductive silicon wafer is an SOI wafer, where an oxide layer of the SOI wafer provides an etch stop for the DRIE etching.

In a further aspect of the invention, the conductive silicon wafer has a resistance of up to 100 ohms-cm.

In another aspect of the invention, the step of removing the handle layer and the buried oxide layer of the SOI wafer includes forming at least one raised or depressed feature incorporated with the membrane and extending above or below the membrane, where the raised or depressed feature moves within the boundaries defined by the cavity. Here the raised feature may also include at least one hole therein.

### BRIEF DESCRIPTION OF THE FIGURES

The objectives and advantages of the present invention will be understood by reading the following detailed description in conjunction with the drawing, in which:

FIGS. 1a-1e show the steps for fabricating the large-area, low-frequency CMUT according to the present invention.

FIGS. 2a-2b show planar cutaway views of the large-area, low-frequency CMUTs according to the present invention.

FIGS. 3a-3b show the performance of the large-area, low-frequency CMUTs with membrane radius according to the present invention.

FIG. 4 shows a photo of a completed four-quadrant device according to the current invention.

FIG. 5 shows an illustration and scanning electron micrographs of silicon pillars in the cavity region prior to the cavity etch step according to the current invention.

FIGS. 6a-6b show the real and imaginary measured input impedance components, respectively, for two of the four wafer quadrants connected in parallel according to the current invention.

FIG. 7a shows frequency responses of the CMUTs determined by measuring the sound pressure level at 3m as a function of ac excitation frequency according to the current invention.

FIG. 7b shows primary and difference frequency beam patterns at 3m of the CMUTs according to the current invention.

FIGS. 8a-8e show the steps for fabricating the large-area, low-frequency CMUT having a SOI wafer according to the present invention.

FIGS. 9a-9e show the steps for fabricating the large-area, low-frequency CMUT having reduced cavity oxide layer thickness according to the present invention.

FIGS. 10a-10f show CMUTs having variations of pistons integrated with the membranes a according to the present invention.

FIGS. 11a-11b show the step of rotating the photoresist mask between exposures of the CMUTs according to the present invention.

### DETAILED DESCRIPTION OF THE INVENTION

Although the following detailed description contains many specifics for the purposes of illustration, anyone of ordinary skill in the art will readily appreciate that many variations and alterations to the following exemplary details are within the scope of the invention. Accordingly, the following preferred embodiment of the invention is set forth without any loss of generality to, and without imposing limitations upon, the claimed invention.

The current invention is a method for manufacturing large-area, low-frequency (the center frequency can range from 10 kHz to 100 kHz) micromachined ultrasonic transducers. These devices are particularly well suited for generating high-intensity ultrasound in air. Their advantages include the possibility of large excitation voltages (500 V or more), tight control over device dimensions and device performance, and high efficiency. The current invention has demonstrated sound pressure levels as high as 140-dB at 50 kHz. The large-area CMUTs are particularly suited for the generation of high-intensity ultrasound in the kilohertz to hundreds of kilohertz frequency range.

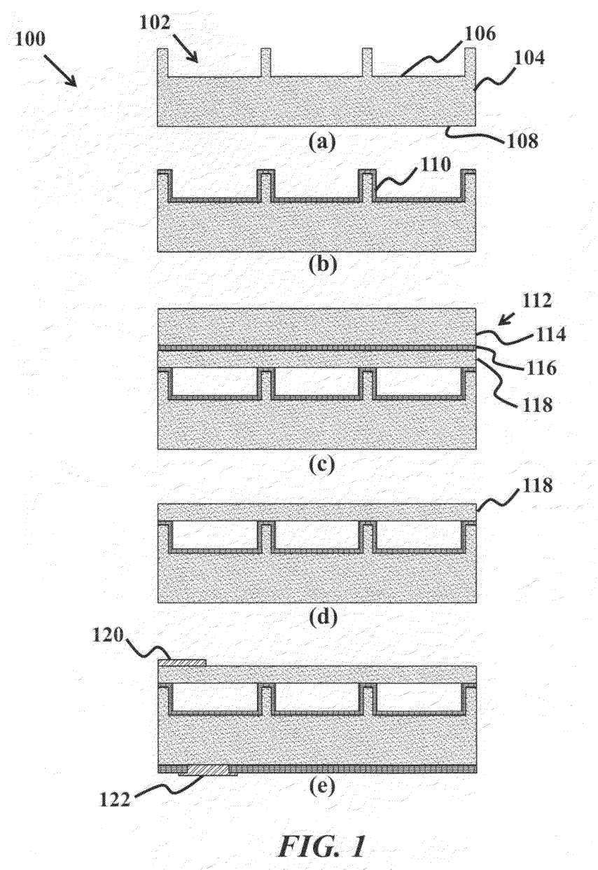

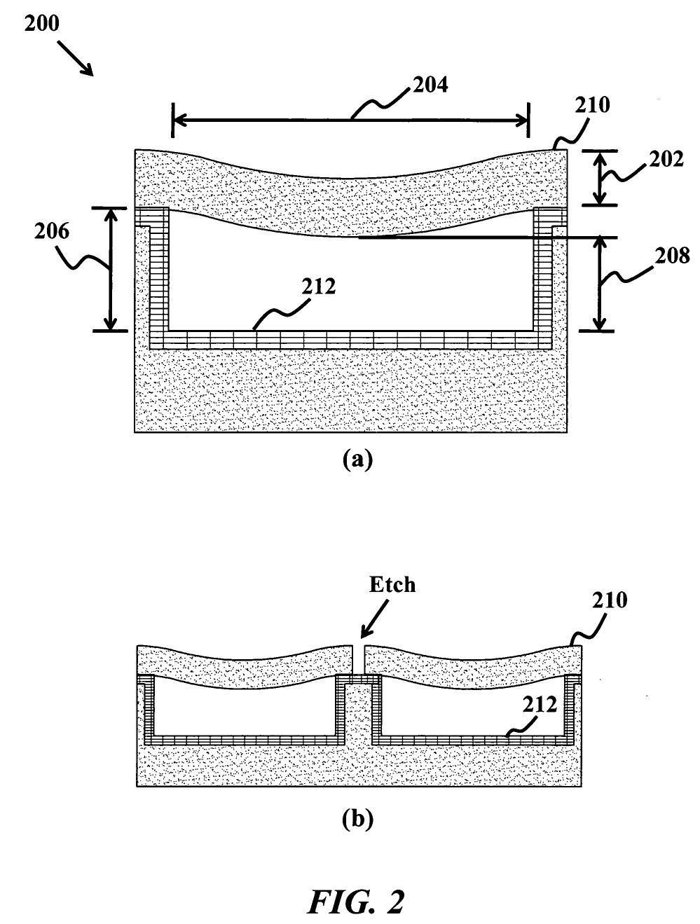

Referring to the figures, FIGS. 1a-1e show a general fabrication method for providing large-area, low-frequency micromachined ultrasonic transducers. As shown in FIG. 1a, the process begins with providing a low resistivity (approximately 0.02 Ω-cm or less) silicon wafer). Because this wafer can act as the bottom electrode of the CMUT, the resistivity must be low enough so that the entire wafer can be considered electrically connected. The basic fabrication steps 100 include, deep reactive ion etching (DRIE) creates cavities 102 in a standard low-resistivity silicon wafer 104. The low resistance of the wafer 104 provides electrical connection between the etched cavity bottom 106 and the wafers back side 108, where metal electrodes are later deposited (see FIG. 1e). The cavities 102 are defined using optical lithography and then etched with DRIE equipment. DRIE is used because it quickly and reliably creates deep cavities. According to one embodiment, the depth of the etched cavities 102, excluding those at the wafer's edge, are within 6% of the mean cavity depth and the cavities 102 at the edge are about 10% to 12% deeper than the mean depth. FIG. 1b shows the step of thermal oxidation creating an electrical insulating layer 110 of silicon dioxide. After the cavities 102 were etched, a 3.3-μm-thick SiO₂ layer is grown at 1100° C. in a wet oxidation furnace. The wafer 104 is then fusion bonded, preferably under vacuum conditions, to a silicon-on-insulator (SOI) wafer having a handle layer 114, a buried oxide layer 116 and a device layer 118, as shown in FIG. 1c. In this embodiment bonding is done with a force of 600 N at a temperature of 50° C. and a pressure of less than 10-5 mbar. Annealing the wafers in a dry oxidation furnace for 3 hours at 1050° C. resulted in a permanent fusion bond between the wafers. FIG. 1d shows a combined step of wafer grinding and chemical etching used to remove the handle 114 and buried oxide layers 116 of the SOI wafer 112. In this exemplary embodiment, the wafer grinding is used to remove all but 100 μm of the handle layer 114. The remaining handle 114 layer silicon is etched away with tetramethylammonium hydroxide (TMAH); the buried oxide layer 116 acted as an etch stop for the TMAH. Dry oxide etching removed the buried oxide layer 116, revealing the membranes 118, where the membrane 118 may be conductive or non-conductive, and where the non-conductive membrane is used an electrode is needed and when the membrane 118 is conductive an electrode may or may not be used. Finally, removal of the conductive membrane 118 between the wafer quadrants (see FIG. 2b) and around the wafer perimeter electrically isolates the devices and prevents the top electrode 120 from shorting with the bottom electrode 122 at the wafer edge. Reactive ion etching opens up areas of oxide on the backside of the wafer for the aluminum electrodes. Finally, FIG. 1e shows metal electrodes (120/122) are deposited on the top and bottom sides of the wafer (FIG. 1d) using standard metal deposition methods (e.g. evaporation followed by lithography and etching).

According to one embodiment of the invention, to slightly simplify the CMUTs fabrication, rather than bonding the etched wafer of FIG. 1b to an SOI wafer 112 of FIG. 1e, the etched wafer of FIG. 1b can be bonded to a thin silicon wafer that has thickness equal to the desired membrane thickness to provide the result shown in FIG. 1d. This variation eliminates the need to remove the SOI buried oxide layer 116 and handle layer 114.

The cavities created with the process shown in FIG. 1 may vary in depth with position on the wafer as a result of DRIE etch-rate nonuniformities. These cavity-depth variations lead to variations in membrane characters that can reduce the CMUTs overall performance.

Wafer bonding method in the current invention provides tight control over device dimensions and results in a single-crystal silicon membrane, which has predictable mechanical properties. Additionally, wafer bonded CMUTs are typically easier to fabricate. For the CMUTs in the current invention, wafer the bonding method provides large-diameter membranes and deep cavities that are required for low frequencies and high output pressures.

The CMUTs in the current invention are useful for transmitting highly directional sound. A directional sound source could be used, for example, in a quiet office space where the source transmits a narrow beam of sound which is audible only to listeners directly on-axis with the source. The directional sound is generated using the parametric array effect. The parametric array is a means of creating a beam of sound that is narrower than conventionally allowed by diffraction.

To generate directional low-frequency sound with a parametric array, the transducer transmits an amplitude modulated ultrasound carrier wave. As this wave propagates, it becomes increasingly distorted due to the nonlinearities of sound propagation. These nonlinearities result in the generation of harmonic components in the audio frequency band (in addition to higher harmonics), a process often referred to as self-demodulation. The beamwidth of the self-demodulated sound is similar to that of the carrier wave, yet at a much lower frequency. In other words, the beam width of the demodulated sound is much narrower than it would be had the sound been radiated directly by the transducer. For example, amplitude modulation of the carrier by a signal with frequency f_{diff}/2 results in transmission of two ultrasound primary frequencies, f₁ and f₂. Self-demodulation of this bifrequency beam produces a narrow beam of sound at the difference frequency f_{diff}=|f2−f1|. The challenge of transmitting sound with parametric arrays in air is to generate primary waves with sufficient intensity to produce desirable sound pressure levels in the audio band.

According to the current invention, the CMUTs for an ultrasound carrier frequency of 50-kHz and a dc bias voltage of less than 1000 V are obtained. As an example, a 50-kHz carrier frequency is provided as a tradeoff between being sufficiently high to produce a reasonably narrow sound beam and being sufficiently low to avoid excessive absorption due to viscosity, heat conduction, and molecular relaxation in the air. Limiting the bias voltage to less than 1000 V allows the use of an insulating layer thickness of several micrometers, which is a thickness easily grown with thermal oxidation and which is comparable to other insulating layer thicknesses successfully used in previously demonstrated CMUT designs.

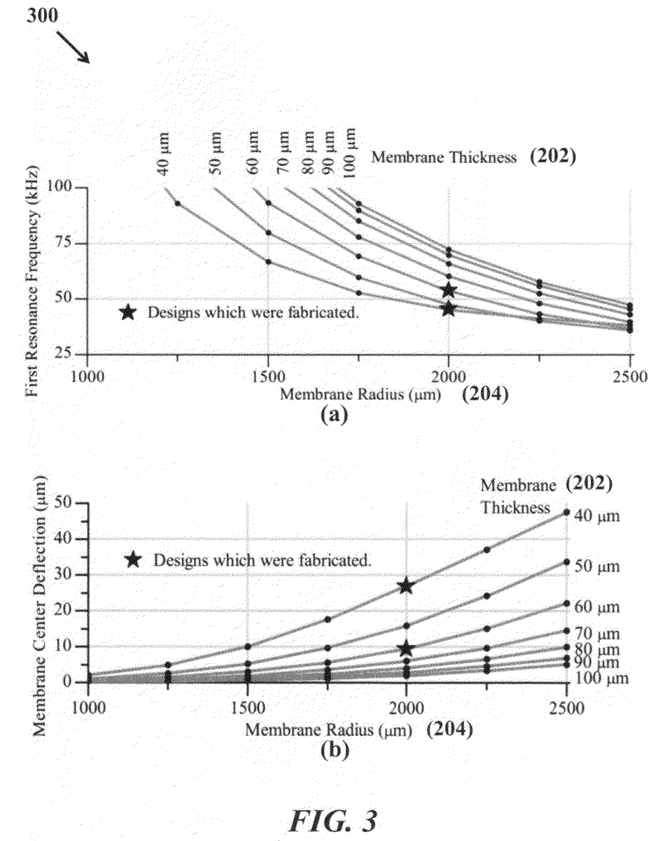

The key device dimensions for the design of a single CMUT cell 200, as shown in FIG. 2a, are the membrane thickness 202, membrane diameter 204, and cavity depth 206. According to this example these dimensions are designed using an axisymetric finite element model (FEM) of the CMUT. This FEM accounts for stress stiffening (with nlgeom turned on), which is significant for membrane deflections that are large relative to the membrane thickness. The FEM was first used to predict membrane diameters and membrane thicknesses that would result in resonance frequencies close to 50 kHz. Next, for design of the cavity depth, the model was used to estimate collapse voltage (the collapse voltage is also commonly referred to as the pull-in voltage); the collapse voltage is the maximum value of the dc bias voltage for a conventionally operated CMUT. FIG. 3 shows a pre-stressed modal analysis 300 of the FEM was used to predict resonance frequency as a function of membrane diameter 204 and thickness 202. For this analysis, a static analysis first calculated the membrane's stress due to atmospheric pressure. The mode frequencies and mode shapes were then calculated based on the stressed model. The membrane deflection becomes larger, either due to atmospheric pressure or an applied dc bias voltage, membrane stress increasingly dictates the resonance frequency. This effect is shown in FIG. 3a, where designs with larger membranes, which have larger deflections due to atmospheric pressure, all converge to a frequency of about 40 kHz. This trend indicates that CMUTs with vacuum-sealed cavities, as in the current invention, for frequencies lower than 40 kHz require very different device designs. Based on the resonance frequency FEM analysis, two membrane designs were fabricated as shown in Table I.

TABLE I
DESIGN DIMENSIONS

| Design | A | B |
|---|---|---|
| Membrane diameter (mm) | 4 | 4 |
| Membrane thickness (μm) | 40 | 60 |
| Cavity depth (μm) | 36 | 16 |
| Oxide thickness (μm) | 3.3 | 3.3 |

These designs have membrane diameters of 4 mm and membrane thicknesses of 40 μm and 60 μm. The cavity depths were selected for these designs with predicted collapse voltages of 888 V and 620 V (Table II) to span a range of bias voltages less than 1000 V. Because the CMUT's cavities are sealed under vacuum according to the current invention, atmospheric pressure in addition to a dc bias voltage results in static membrane deflection as shown in FIG. 3b. For the two device designs, the FEM was used to calculate the static deflection at the membrane's center with a dc bias voltage equal to 80% of the collapse voltage as shown in Table II.

TABLE II
DESIGN CALCULATIONS AND SIMULATION RESULTS

| Design | A | B |
|---|---|---|
| Resonance Frequency, FEM (kHz) | 46 | 54 |
| Membrane Center Deflection from Atmo- | 27 | 9.9 |
| spheric Pressure, FEM (μm) | | |
| Collapse Voltage, FEM (V) | 880 | 620 |
| Center Deflection with 80% of Collapse | 29.0 | 11.3 |
| Voltage Applied, FEM (μm) | | |
| Ratio of Center Deflection to Average De- | 3.2 | 3.2 |
| flection (r_{pk2avg}), FEM | | |
| Maximum Average Displacement from (1) | 1.92 | 1.32 |
| (μm) | | |
| Maximum RMS Pressure Predicted from (2) | 138 | 136 |
| (dB re 20 μPa) | | |

From this calculated deflection, the distance 208 between the bottom of the deflected membrane 210 and the top of the oxide layer 212 can be found, as shown in FIG. 2, which gives a rough indication of the maximum possible downward ac membrane displacement. From this maximum displacement, the maximum displacement is estimated that is spatially averaged over the entire device using

d_{avg,ac}=(d_{cav}−dₐₜₘ−d_{dc})r_{fill}/r_{pk2avg} (1),

which in turn allows estimation of the maximum output pressure of the device. In (1), d_{avg,ac} is the maximum spatially averaged membrane displacement, d_{cav} is the cavity depth, dₐₜₘ is the deflection due to atmospheric pressure, and d_{dc} is the deflection due to dc bias.

The fill factor, r_{fill}, is the fraction of the device area occupied by membranes; in this case, the layout of the circular membranes has a fill factor of 88%. The value of r_{pk2avg} gives the ratio of peak ac displacement at the center of the membrane 210 to displacement averaged over the entire membrane 210, where the membrane 210 moves up and down more at the center than at the edge. r_{pk2avg} is estimated with the FEM for small changes in dc bias voltage. From the average displacement, (2) gives the magnitude of the RMS acoustic pressure averaged over the surface of the transducer 200, where Zₐᵢᵣ is the acoustic impedance of air, and f is frequency.

P_{avg}=2πfd_{avg}Zₐᵢᵣ/\sqrt{2} (2)

Because the transducer 200 is much larger than the wavelength of 50-kHz ultrasound in air (6.9 mm), the plane wave acoustic impedance of air was used, which is 413 Rayls. Table II summarizes the pressure calculations. These calculations give only a rough estimate of maximum achievable acoustic pressure. However, they help guide the device design and ultimately the predicted values match the measured results with reasonable accuracy. To generate large sound pressure levels, the insulating oxide 212 should withstand voltages at least as large as the device's collapse voltage. The thickness and quality of the insulating oxide 212 determines the maximum voltage that can be applied before breakdown. The theoretical breakdown voltage of SiO₂ is about 1000 V/μm; breakdown voltages closer to 400 V/μm have been observed by the inventors. For the CMUTs presented in this example, an oxide 212 thickness of 3.3 μm is used, which is thicker than required based on a 400 V/μm breakdown voltage and the simulated collapse voltages. However, because the oxide covers such a large area, it is more likely that there will be defects somewhere in the oxide 212 that will reduce the breakdown voltage. A drawback of thicker oxide 212 is that it occupies more of the cavity. Furthermore, charges trapped in the oxide 212 can drift over time and change the electric field in the cavity, which can cause the device's performance to change over time.

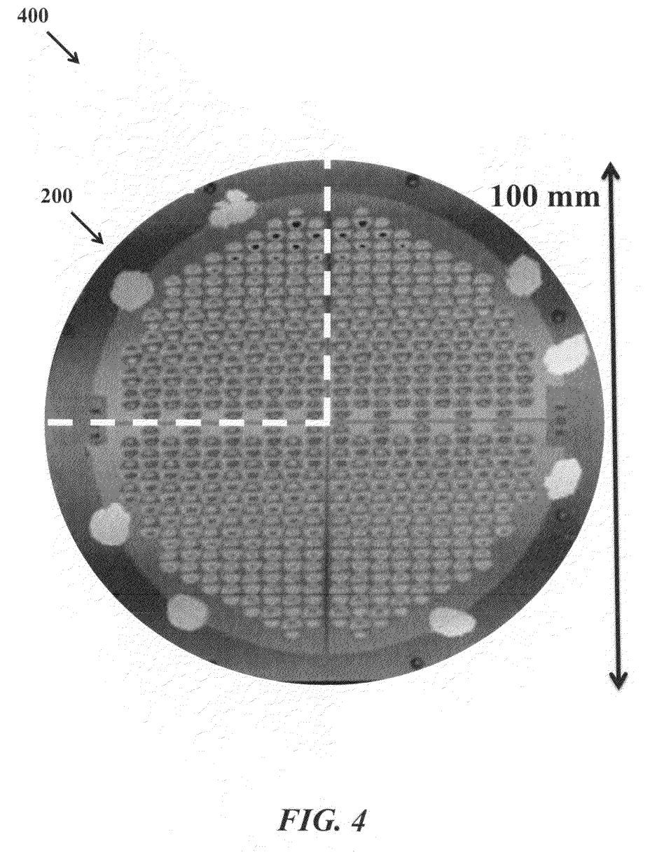

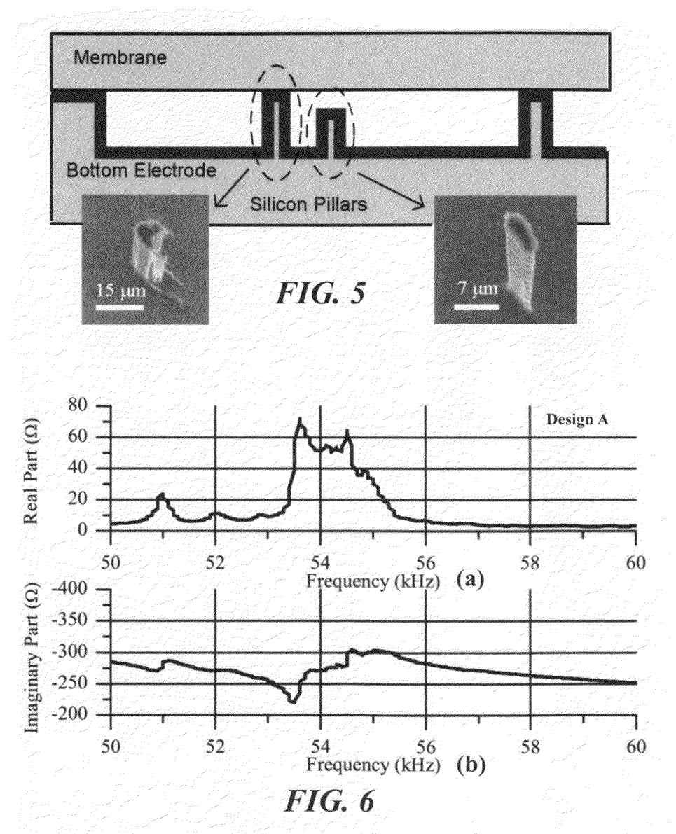

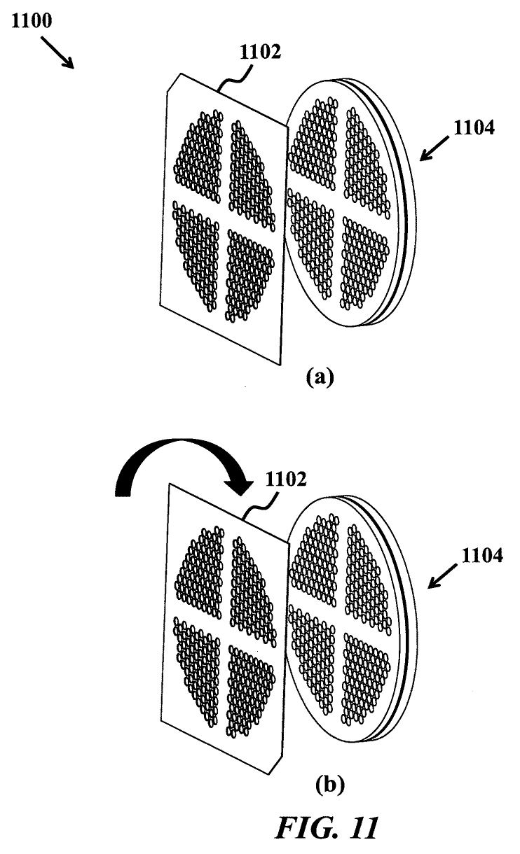

The fabrication process of the current invention is based on direct wafer bonding to fabricate the CMUTs. In one aspect of the invention, each wafer, for example a 100-mm wafer 400 as shown in FIG. 4, comprises only four devices 200 having multiple cavities 106 covered by four separate membranes 118, where a short or defect in the insulating oxide 212 at any point on a device affects the device as a whole. A challenge exits to etch the cavities without leaving pillars of unetched silicon (see FIG. 5). These pillars result from leftover photoresist or particles present in the cavity regions that act as a mask to the DRIE cavity etching; they obstruct the membrane deflection and if not covered with thick oxide can short the device or limit its breakdown voltage. The large device area makes it particularly challenging to ensure a device is free of pillars. Most of the pillars can be prevented in the lithography step used to define the cavity areas. For this lithography, a second exposure is used to ensure that no unexposed photoresist was left in the cavity areas. Between exposures, the mask used for the photolithography is rotated, in this example the rotation is 180° (the mask is symmetric, see FIGS. 11a-11b) to ensure that defects on the mask do not result in unexposed photoresist. Furthermore, the mask is cleaned prior to each exposure. Even with careful particle prevention and attention to the cavity lithography step, silicon pillars can appeared after an anisotropic DRIE cavity etch (FIG. 5). To prevent these pillars, an isotropic DRIE cavity etch is used. Isotropic etching undercuts defects on the wafer that are small relative to the cavity depth and thus etches away pillars that are tall and narrow.

When a second exposure is used for the cavity lithography combined with isotropic cavity etching, most of the fabricated wafers had no observable pillars. The remaining pillars are covered with a thick layer of oxide and thus do not short the device.

Presented are fabricated and characterized devices with the two exemplary designs given in Table I. The devices were first characterized by measuring their electrical input impedance with an impedance analyzer. Design A and B devices have strong resonances at 45 kHz and 54 kHz, where FIG. 6 shows the frequency response for design A. The impedance measurements also show small off-resonance peaks, which are partly a result of variations in membrane thickness and cavity depth between CMUT cells. For example, membranes at the wafer's edge have a higher resonance frequency because they experience less spring softening. Spring softening reduces the membrane's resonance frequency by an amount determined by the ratio of the applied dc bias voltage to the collapse voltage; the membranes at the edge have deeper cavities resulting in larger collapse voltages and higher resonance frequencies.

To measure output pressure and beam patterns, the devices are mounted on a rotational stage and measured their output with a calibrated microphone. A function generator followed by an amplifier generated a 200-Vpeak-to-peakacexcitationvoltage. As the applied dc bias voltage was increased, the pressure produced by the CMUTs increased until a saturation point was reached, where further increases in dc bias voltage resulted in only small gains in measured acoustic pressure. The dc bias voltage was set to the start of this saturation point to minimize the risk of electrical breakdown of the oxide insulation layer.

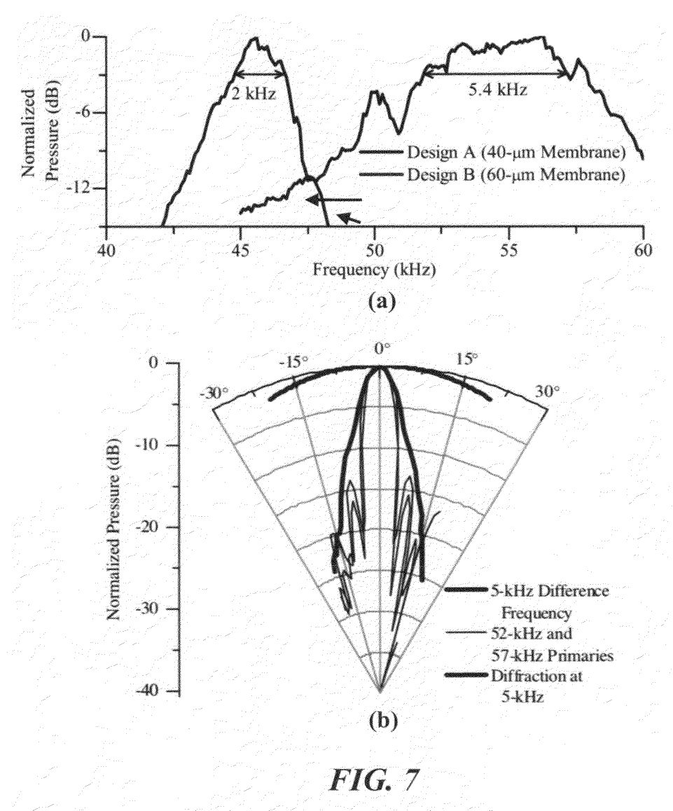

At a distance of 3 m, the microphone was used to measure the acoustic pressures generated by the CMUTs as a function of an excitation frequency, shown in FIG. 7a and in Table III. For these measurements, just two of the four wafer quadrants were excited in parallel in order to separately characterize the wafer halve sand to decrease the risk of damaging the entire wafer. The measured frequency responses show that the fabricated CMUTs have center frequencies close to the resonance frequencies predicted by finite element modeling (Table II). To estimate the acoustic pressure generated at the face of the CMUTs, the source sound pressure levels needed to generate the sound pressure levels was simulated measured at 3 m (the simulation method is described below). At the face of the devices, the design-A and design-B CMUTs produced estimated average acoustic source levels of 135.3 dB and 128.9 dB, respectively. Measurements made with an interferometer of displacement at different positions on the wafer indicate that membranes at the edge have about one-half the displacement of membranes in the center; this variation in displacement results from the variation in cavity depth. When this variation in displacement across the wafer is accounted for, the estimated acoustic source levels at the center of the wafer for the design-A and design-B CMUTs is 138.1 dB and 131.5 dB, respectively.

TABLE III
SUMMARY OF MEASUREMENTS

| Design | A | B |
|---|---|---|
| Atmospheric Deflection (μm) | 29.1 | 10.1 |
| AC excitation (V peak-to-peak) | 200 | 200 |
| DC bias (V) | 380 | 350 |
| Center frequency (kHz) | 46 | 55 |
| Bandwidth (kHz) | 2.0 | 5.4 |
| Pressure at 3 m (dB re 20 μPa RMS) | 114 | 107 |
| Pressure normalized to 0 m (dB re 20 μPa RMS) | 135 | 129 |

The design-B CMUT produced less pressure than the maximum value predicted by the design calculations (Table II). However, the combination of power supply and function generator limited the excitation voltage to 200Vpeak-to-peak. Larger excitation voltages could be used to generate higher sound pressure levels.

A design-B CMUT was used to transmit 5-kHz sound with a parametric array. The sum of two 100-V ac excitation signals 5-kHz apart in frequency drove the four quadrants of the CMUT. The resulting primary frequency and difference frequency beam patterns, shown in FIG. 7b demonstrate transmission of a narrow beam of sound. The 5-kHz sound was clearly heard along the CMUT's axis; at 3 m, the level of the 5-kHz sound was 58 dB. For comparison, the sound level of normal conversation is about 60 dB.

For these beam pattern measurements, the entire CMUT was excited with the sum of the primary signals. Ideally, the primaries would be transmitted from separate interleaved parts of the transducer to prevent nonlinearities in the transducer from directly radiating sound at the difference frequency.

A comparison between driving the CMUT with the sum of the primary frequency signals and driving separate wafer quadrants with separate primary signals, showed that driving the CMUT with the sum resulted in similar sound pressure levels at the difference frequency and just a slightly wider sound beam, indicating transducer nonlinearities were not a significant source of difference frequency sound.

Nonlinearities at the receiver can also result in spurious difference-frequency sound generation. It is noted two sources of difference-frequency sound at the receiver; both are associated with the primary waves' interaction with the microphone. The first source is due to nonlinearity in the microphone and its electronics; the second source is due to acoustic radiation pressure—the latter is also referred as pseudosound. Because both sources are proportional to the product of the two primary wave amplitudes at the location of the microphone, their spatial dependencies are indistinguishable. Spurious difference-frequency generation at the receiver is referred to here generically as detector nonlinearity, irrespective of whether it is due to pseudosound or nonlinearity in the receiver system. Detector nonlinearity results in a directivity function for the difference frequency that is proportional to the product of the directivity functions of the two primary frequencies. Thus, the resulting difference frequency beam width is narrower than that for either primary frequency. The resulting beam width is also narrower than the beam width of the difference frequency generated by the parametric array. Because the effect of the parametric array relative to detector nonlinearity increases with distance from the source, the difference frequency beamwidth are expected to increase with distance. And, indeed, it was observed that the beamwidth at the difference frequency increased from about 7° at 1 m to 9° at 3 m as sound resulting from detector nonlinearity gave way to sound from the parametric array.

To remove the contribution of microphone nonlinearity to detector nonlinearity, an acoustic low-pass filter can be placed in front of the microphone. This filter passes the difference frequencies but attenuates the high-intensity primary waves that result in spurious difference frequency generation due to the microphone's nonlinearity. Measurements of the sound pressure levels at the difference frequency were made, both with and without the acoustic filter, as a function of distance along the beam axis and compared the results with simulations, as shown in FIG. 7b. For these measurements, the primary waves were generated with separate quadrants of the source transducer. Numbered in the clockwise direction, quadrants 1 and 3 radiated one primary frequency, and quadrants 2 and 4 radiated the other primary frequency such that the source geometry for each primary wave resembled a bow tie. This configuration was used to avoid any possibility of the source producing difference frequency directly due to its inherent nonlinearity. Additionally, it interleaved the sources of the two primary frequencies to the greatest extent possible with the given source design. The curves shown in FIG. 7b are simulations obtained from numerical solutions of the KZK equation that account for nonlinearity, diffraction, thermoviscous absorption, and atmospheric absorption due to molecular relaxation. Although the specific numerical algorithm used simulates axisymmetric sound fields, it proved to be sufficiently accurate for difference frequency calculations despite the asymmetry of the source geometry. The source was thus modeled as a circular disk of diameter 5.3 cm to match the surface area of each bow tie, which is to say that the diameter of the active area was divided of the full circular CMUT, 7.5 cm, by \sqrt{2}. The source levels that produced the best fit with the measurements was then chosen at the difference frequency, and these were found to be 121 dB at each of the primary frequencies, 48.5 kHz and 53.5 kHz.

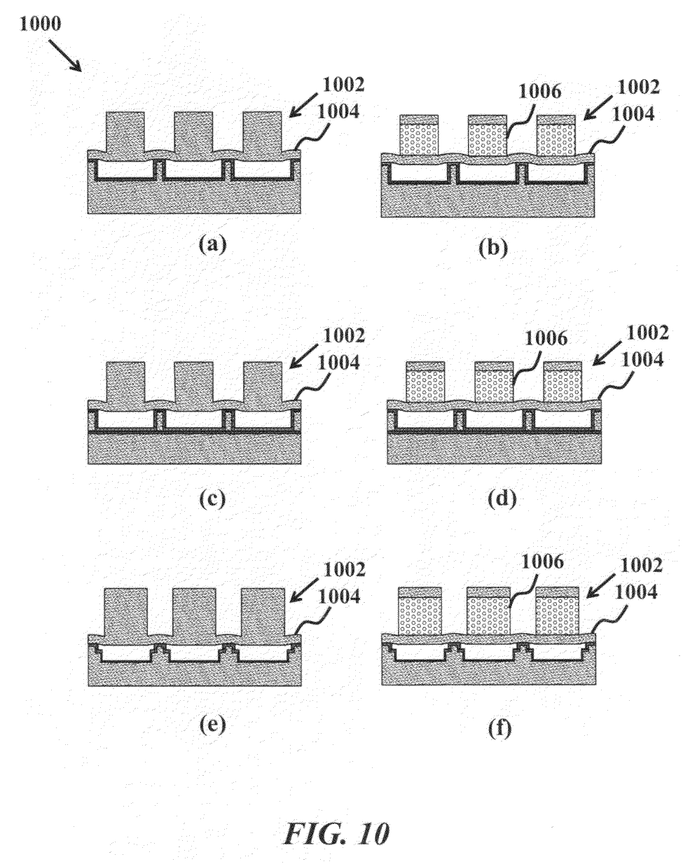

For the stated source conditions, the sound pressure level was simulated at the difference frequency due to the parametric array effect alone, which we denote by p pa, and the sound pressure level due to the combination of the parametric array and detector nonlinearity, which we denote by pₚₑᵣ, where pₚₑᵣ=pₚₐ+p_{dn}. A quadratic component was assumed to dominate the detector nonlinearity, p_{dn}. Therefore, the detector nonlinearity was modeled using p_{dn}=Kₚ₁ₚ₂, where p1 and p2 are the peak pressure amplitudes of the primary waves at the microphone location, and K is a constant determined by best fit with the measurements. From the measurements shown in FIG. 10, we determined that K=(2×10⁻⁴ Pa⁻¹). For this value of K, the simulated difference frequency sound levels match the measured levels very well with distance as shown in FIG. 7b.

It was observed how detector nonlinearity dominates the measurements close to the source, but beyond about 3 m its effect is negligible and only the contribution from the parametric array is measured at the difference frequency. Having found a value for K that agrees with the measured pressure levels, the source of detector nonlinearity can be investigated. Consider first the contribution due to radiation pressure (pseudosound). The radiation pressure on a surface (e.g., the face of a microphone) due to reflection of a sound beam is taken to be p_{rad}=2 [symbol] E [symbol] , where [symbol] E [symbol] is the time-averaged energy density in the incident beam. When evaluated for the radiation pressure at the difference frequency, the relation may be rewritten as p_{rad}=K_{rad}p₁p₂, where Krad=1.4×10-5 Pa-1 for air at room temperature. Since K_{rad}=0.07K, the contribution due to radiation pressure is too low to account for the detector nonlinearity.

Now observe from FIG. 7b that the levels of the difference frequency due to detector nonlinearity are about 45 to 50 dB below the peak level in the primary beam. The corresponding harmonic distortion is thus between 0.3% and 0.6% in terms of amplitude ratio. Since the microphone specifications in this example state only that the total harmonic distortion is less than 1%, it is most likely that the source of our detector nonlinearity was the microphone assembly, which includes the capacitive transducer and preamplifier. Because the relative contributions of detector nonlinearity and the parametric array vary with distance from the source, the frequency response of the directional sound also varies with distance. This frequency dependence means that the perceived sound pressure level at the difference frequency for fixed primary source levels varies with the difference frequency. The detector nonlinearity contribution of the sound pressure level (characterized by the constant K) has very little frequency dependence because radiation pressure is independent of frequency and because we expect microphone nonlinearity to vary weakly with frequency. The contribution to the sound pressure level generated by the parametric array, which dominates for distances far from the source, varies with frequency in proportion to f_{diff}ⁿ, where n depends primarily on the ratio of diffraction length (the area of the transmitter divided by the wavelength at the primary frequencies) to absorption length (the inverse of the nominal absorption coefficient at the primary frequencies). Numerical solutions of the KZK equation for the conditions of our experiments indicate n approximately equal to 1.5, which predicts that the sound pressure level at the difference frequency will increase by 9 dB per octave. The significance of n for audio applications is that it is also the order of the time derivative that, when applied to the square of the envelope modulating the amplitude of the carrier wave, yields the demodulated acoustic waveform along the axis of the parametric array. It therefore suggests the form of predistortion required for the transmission of speech.

To examine the frequency dependence experimentally, unfiltered sound pressure levels were measured at difference frequencies of 1 kHz, 3 kHz, and 5 kHz at distances from 0.5 m to 2.5 m. Because the sound pressure levels at the primary frequencies varied slightly between experiments, the measured sound pressures were normalized at the difference frequency by the product of sound pressures at the primary frequencies. At 0.5 m, the normalized sound levels at the three difference frequencies were within 1 dB of each other. A lack of frequency dependence was expected at this distance, where detector nonlinearity dominates the effect of the parametric array. At 2.5 m, where the relative effect of the parametric array is more significant, the sound level at 5 kHz was 3.5 dB higher than at 3 kHz and 7 dB higher than at 1 kHz. This dependence on frequency is weaker than f_{diff}^{1.5} because at 2.5 m detector nonlinearity still contributes to the measured difference frequency signal.

Most of the measurements for were made using a 5-kHz difference frequency because it results in high sound pressure levels that are easy to measure over a range of distances and detector angles. However, intelligible speech requires a bandwidth extending from approximately 300 Hz to 3 kHz. At 3 m, the inventors produced 5-kHz sound pressure levels up to 58 dB. Transmission of speech at similar sound pressure levels and across similar distances requires higher source pressure levels at the primary frequencies, particularly for frequencies at the low end of the frequency spectrum of speech. Since the difference frequency pressure increases with the surface area of the source, tiling together rectangular-shaped CMUTs to create a larger source would be one way to achieve higher sound pressure levels at the primary frequencies and therefore higher levels at the difference frequency. Additionally, CMUTs with a thicker insulating layer and deeper cavities could be designed to produce higher source levels with larger excitation voltages.

The results demonstrate that with wafer bonding fabrication methods can make low-frequency CMUTs to transmit sound using a parametric array. The large area of the CMUTs presented the biggest fabrication challenge. Each fabrication step should be adapted to prevent defects. Furthermore, the device should be robust enough to tolerate the fabrication defects that cannot be prevented.

The CMUTs produced high intensity 50-kHz ultrasound sufficient to transmit a narrow beam of clearly audible 5 kHz sound with a parametric array over several meters. In order to transmit wide band audio, such as speech, over similar distances, several CMUT devices could be combined to create a large-area source. Alternatively, the CMUTs could be redesigned to generate higher pressures with larger excitation voltages.

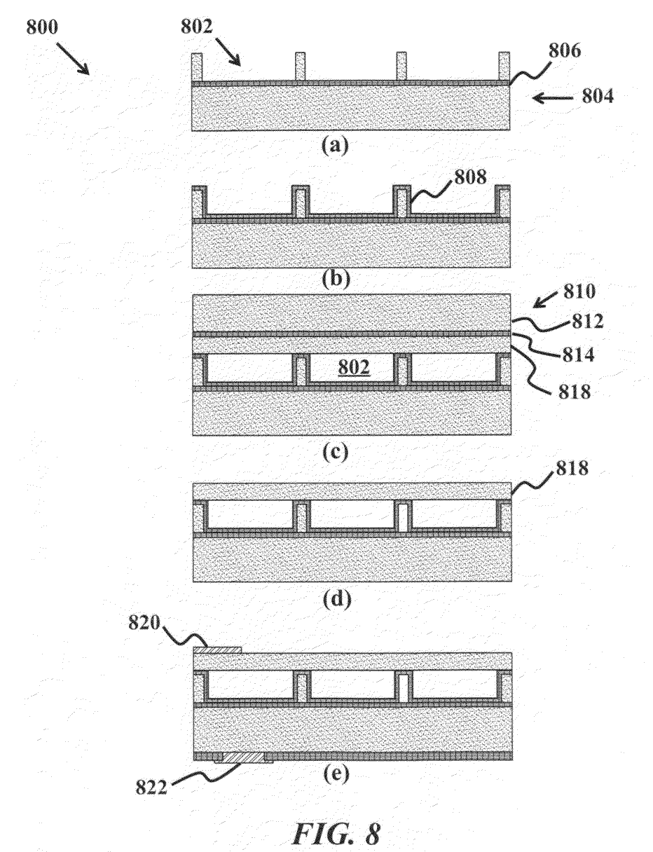

Described here are some exemplary variations and embodiments according to the current invention. In one aspect of the invention, to reduce the cavity depth variation, FIGS. 8a-8e show the fabrication steps 800 where the cavities 802 can be created in an SOI wafer 804. The buried oxide layer 806 of the SOI wafer 804 acts as an etch stop, ensuring uniform cavity 802 depths. Additionally, the buried oxide layer 806 contributes to the total insulating oxide thickness. As a result, shorter thermal oxidation times can be used to create an oxide layer of a specific thickness. Reduced thermal oxidation time particularly benefits designs that require a very thick (e.g. greater than 4 μm) oxide layer. As described in FIG. 1 the cavities 802 are defined using optical lithography and then etched with DRIE equipment. FIG. 8b shows the step of thermal oxidation creating an electrical insulating layer 808 of silicon dioxide. FIG. 8c shows the wafer 804 is then fusion bonded, preferably under vacuum conditions, to a silicon-on-insulator (SOI) wafer 810 having a handle layer 812, a buried oxide layer 814 and a device layer 816. FIG. 8d shows a combined step of wafer grinding and chemical etching used to remove the handle 812 and buried oxide layers 814 of the SOI wafer 810, as described above, where a membrane 818 is formed across the cavities 802. Finally, FIG. 8e shows metal electrodes (820/822) are deposited on the top and bottom sides of the wafer using standard metal deposition methods (e.g. evaporation followed by lithography and etching).

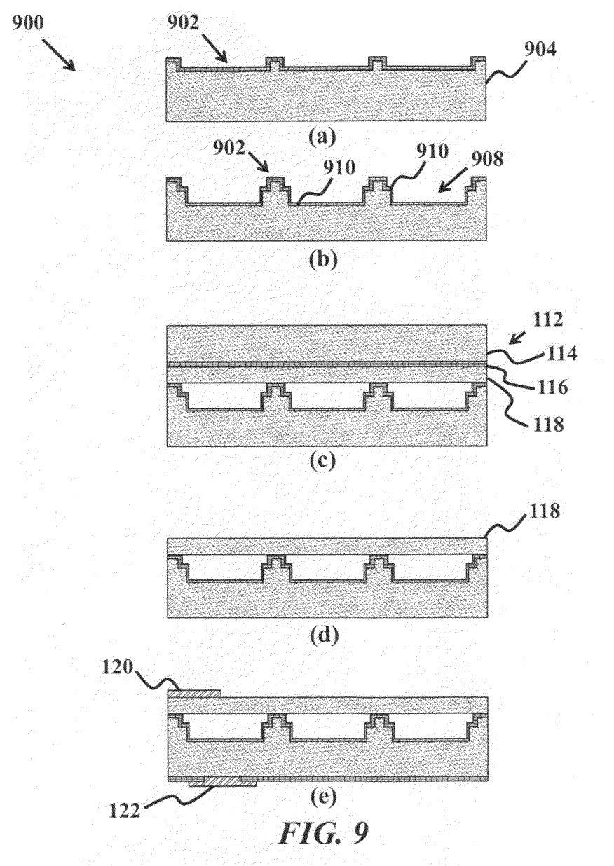

A further variation of the current invention is shown in FIGS. 9a-9e, using a two etch step process 900 to create the device's cavities. In the first step, shown in FIG. 9a, DRIE creates a shallow cavity 902 (e.g. several microns deep) in a silicon wafer 904. Next, thermal oxidation creates a thick layer of oxide 906, as shown in FIG. 9b, that is subsequently patterned and etched. A second DRIE etch step creates a deep cavity 908. A second thermal oxidation creates a thin layer of oxide 910 inside the shallow and deep cavities (902/908). The second oxidation 910 slightly raises the thick oxide layer at the edge of the cavities (902/908), creating a small bump 912. The shallow cavity 902 prevents this bump 912 from affecting the wafers 904 surface, which must be smooth for successful wafer bonding.

Steps shown in FIGS. 9c-9e are similar to those in FIGS. 1 and 8. This variation on the basic fabrication method reduces the thickness of oxide inside the cavity. Charges trapped inside the oxide can drift over time when high voltages are applied to the device. These drifting charges can cause the device performance to change with time. Reducing the amount of oxide inside the cavity reduces this effect. Retaining a thin layer of oxide prevents surface conduction along the sides of the cavity.

According to another embodiment of the current invention, FIGS. 10a-10f show a variation 1000 of the current invention where, instead of simply removing the handle layer of the SOI wafer, DRIE etches away the handle-layer silicon leaving columns 1002 of unetched silicon in the center portion of the membrane 1004. These columns 1002 create a flat membrane surface that increases the devices transmit and receive sensitivity. The columns can be solid or can have holes 1006 etched in them (e.g. in a honeycomb pattern) to reduce their mass. The columns 1002 may also have a honeycomb sandwich structure, which provides large column stiffness with minimal mass.

FIGS. 11a-11b show the step of rotating 1100 the photoresist mask 1102 between exposures of the CMUTs 1104 according to the present invention. Because the photoresist is symmetric, the rotation, in this instance 180°, aligns with the previous exposure step. This process results in removing any spurious defects in the cavity as discussed above.

In each of the described embodiments of the fabrication method, the CMUTs cavities are sealed under vacuum to eliminate losses due to squeeze film damping. However, some designs may require squeeze film damping to achieve very wide bandwidths. Additionally, for some applications, static pressure may result in very large static membrane deflections that cannot be tolerated. In these situations, holes from the back side or vent channels on the front side can equalize the pressure on the front and back side of the membrane.

The current invention provides devices primarily for generating high-intensity 40 to 60-kHz ultrasound for transmitting directional audio using the parametric array effect (sometimes called an acoustic spotlight). A directional sound source can transmit audio with a beam width that is much narrower (greater than 10-times narrower) than sound transmitted with a conventional sound source.

There is tremendous commercial opportunity for directional sound. For example, directional sources could be used in laptops or cellphones so users can listen to sound privately without headphones. Directional sound sources have already found application in museums and billboard advertising.

The CMUTs provided according to the current invention may enable widespread use of directional audio based on the parametric array effect. These devices can efficiently generate the high-intensity ultrasound required for transmitting directional audio with a parametric array. Further, the devices according to the current invention, are well suited to a range of low-frequency applications. For example, they could also be used for the transmission and detection of sonar or as conventional microphones.

Some applications of the current invention include:
Highly directional audio. Using the parametric array effect, the devices can be used to create narrow beams of sound. These sources can be used to localize sound to a particular area or person.
Sonar. The devices could be used to transmit and detect sonar.
Flow meters. Airborne ultrasound is often used to measure flow rates.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example a thin wafer with thickness equal to the membrane wafer could be used in place of the SOI wafer, the membrane layer could be etched to both electrically isolate cells and reduce parasitic capacitance, holes or channels could be created to the cavities to vent them to the atmosphere, the metal electrode layers on the top and bottom sides could uniformly cover the array or could be patterned to, for example, reduce its load on the cells or reduce parasitic capacitance.

All such variations are considered to be within the scope and spirit of the present invention as defined by the following claims and their legal equivalents.

What is claimed is:

1. A method of fabricating low-frequency and high-intensity ultrasound CMUTs comprising:
a. using deep reactive ion (DRIE) etching to etch at least one cavity in a first surface of a conductive silicon wafer;
b. growing an insulating layer on at least said first surface of said conductive silicon wafer;
c. bonding a conductive silicon layer of a SOI wafer to said insulating layer, wherein said SOI wafer comprises a handle layer, a buried oxide layer and said conductive silicon layer;
d. removing said handle layer and said buried oxide layer of said SOI wafer, wherein said conductive layer of said SOI wafer forms a membrane across said at least one cavity; and
e. electrically isolating at least one said membrane across said at least one cavity, wherein at least one said low-frequency and high-intensity ultrasound CMUT is provided.

2. The method of fabricating low-frequency and high-intensity ultrasound CMUTs of claim 1, further comprises providing an electrode on said membrane.

3. The method of fabricating low-frequency and high-intensity ultrasound CMUTs of claim 1, wherein said bonding is done in a vacuum environment to provide a vacuum-sealed cavity.

4. The method of fabricating low-frequency and high-intensity ultrasound CMUTs of claim 1, wherein said bonding comprises annealing in an oxidation furnace.

5. The method of fabricating low-frequency and high-intensity ultrasound CMUTs of claim 1, wherein said removing said handle layer and said buried oxide layer comprises grinding and etching.

6. The method of fabricating low-frequency and high-intensity ultrasound CMUTs of claim 1, further comprises providing an electrode on a second surface of said conductive silicon wafer.

7. The method of fabricating low-frequency and high-intensity ultrasound CMUTs of claim 1, wherein a profile of said at least one cavity is defined by optical lithography.

8. The method of fabricating low-frequency and high-intensity ultrasound CMUTs of claim 7, wherein said optical lithography comprises a first optical exposure and at least a second optical exposure, wherein a mask of said photolithography is rotated between said exposures.

9. The method of fabricating low-frequency and high-intensity ultrasound CMUTs of claim 8, wherein said mask is cleaned between each said exposure.

10. The method of fabricating low-frequency and high-intensity ultrasound CMUTs of claim 1, wherein said DRIE etching comprises anisotropic DRIE etching or isotropic DRIE etching.

11. The method of fabricating low-frequency and high-intensity ultrasound CMUTs of claim 1, wherein a thickness of said membrane is in a range of 1 μm to 500 μm.

12. The method of fabricating low-frequency and high-intensity ultrasound CMUTs of claim 1, wherein a cross-section length of said membrane is in a range of about 100 μm to 10 mm.

13. The method of fabricating low-frequency and high-intensity ultrasound CMUTs of claim 1, wherein a depth of said cavity is in a range of 1 μm to 500 μm.

14. The method of fabricating low-frequency and high-intensity ultrasound CMUTs of claim 1, wherein a cross-section length of said cavity is in a range 100 μm to 10 mm.

15. The method of fabricating low-frequency and high-intensity ultrasound CMUTs of claim 1, wherein a ratio of a cross-section length to of said membrane a thickness of said membrane is in a range of 0.01 to 500.

16. The method of fabricating low-frequency and high-intensity ultrasound CMUTs of claim 1, wherein said conductive silicon wafer is an SOI wafer, wherein an oxide layer of said SOI wafer provides an etch stop for said DRIE etching.

17. The method of fabricating low-frequency and high-intensity ultrasound CMUTs of claim 1, wherein said conductive silicon wafer has a resistance of up to 100 ohms-cm.

18. The method of fabricating low-frequency and high-intensity ultrasound CMUTs of claim 1, wherein said removing said handle layer and said buried oxide layer of said SOI wafer comprises forming at least one raised feature or at least one lowered feature incorporated with said membrane and extending above or extending below said membrane, wherein said raised feature or said lowered feature moves within the boundaries defined by said cavity.

19. The method of fabricating low-frequency and high-intensity ultrasound CMUTs of claim 18, wherein said raised feature comprises at least one hole therein.
